(19) United States
(12) Patent Application Publication
(10) Pub. No.: US 2009/0184373 A1
(43) Pub. Date: Jul. 23, 2009

(54) SEMICONDUCTOR DEVICE AND METHOD FOR MANUFACTURING A SEMICONDUCTOR DEVICE

(75) Inventors: Winfried Kaindl, Unterhaching (DE); Michael Treu, Villach (AT); Holger Kapels, Holzkirchen (DE); Carolin Tolksdorf, Steinhoering (DE); Armin Willmeroth, Augsburg (DE)

Correspondence Address: DICKSTEIN SHAPIRO LLP, 1177 AVENUE OF THE AMERICAS 6TH AVENUE, NEW YORK, NY, 10036-2714, US

(73) Assignee: Infineon Technologies Austria AG, Villach (AT)

(21) Appl. No.: 12/016,478

(22) Filed: Jan. 18, 2008

(51) Int. Cl. H01L 29/00; H01L 21/3205

(52) U.S. Cl. 257/364; 438/585; 257/E29.001; 257/E21.294

(57) ABSTRACT

A semiconductor device is provided which has a semiconductor substrate. An active cell area having at least one active cell is formed in the semiconductor substrate, wherein at least sections of the active cell area are surrounded by an edge termination region. An integrated gate runner structure is arranged at least partially in the edge termination region and has at least one low electrical resistance portion and at least one high electrical resistance portion which are electrically connected in series with each other.

This description refers to embodiments of semiconductor devices and particularly to power semiconductor devices having an integrated gate runner structure with an adjusted gate resistance. Further embodiments refer to a method for manufacturing a semiconductor device.

### BACKGROUND OF THE INVENTION

Power semiconductor devices such as compensation devices, also known as CoolMOS, exhibit a low specific on-state resistance (Ron*A) and can be formed at reduced size with respect to conventional MOSFETs while maintaining the low on-state resistance. The reduced size also results in smaller capacities which allow fast switching with steeper switching slopes.

When using such high speed power semiconductor devices care must be taken to match the semiconductor device with parasitics in the application. For example, in non-optimised applications having relatively large parasitic inductances or capacitances a fast switching device can induce steep changes of the current and voltage which could result in high-frequent oscillations which may adversely affect the EMI-behaviour of the device or might bring the device outside of operational standards.

Many applications try to tailor the gate-drain capacitance, also known as Miller capacitance, to compensate the oscillations. This, however, may cause significant changes to the layout of the device.

### BRIEF SUMMARY OF THE INVENTION

According to an embodiment, a semiconductor device is provided which includes a semiconductor substrate and an active cell area having at least one active cell formed in the semiconductor substrate. An edge termination region surrounds at least sections of the active cell area. An integrated gate runner structure is arranged at least partially in the edge termination region and has at least one low electrical resistance portion and at least one high electrical resistance portion. The high electrical resistance portion is electrically connected in series to the low electrical resistance portion.

By providing high and low electrical resistance portions the resistance of the gate runner structure can be adjusted. This changes the effective gate resistance and, therefore, influences the switching behaviour of the semiconductor device. Steep oscillations can be avoided. Furthermore, the effective gate resistance can be varied according to specific needs so that tailored devices can be provided.

### BRIEF DESCRIPTION OF THE SEVERAL VIEWS OF THE DRAWINGS

A full and enabling disclosure of the present invention, including the best mode thereof, to one of ordinary skill in the art, is set forth more particularly in the remainder of the specification, including reference to the accompanying figures. Therein:

FIG. 1 shows a plain view on a semiconductor device according to a first embodiment.

FIG. 2 shows a cross-sectional view along the line AB in FIG. 1.

FIG. 3 shows a cross-sectional view along the line AB in FIG. 1 according to another embodiment.

FIG. 4 shows a plain view on a semiconductor device according to a further embodiment having two long low electrical resistance portions at opposite sides of the gate runner structure.

FIG. 5 shows a plain view on a semiconductor device according to a further embodiment having low electrical resistance portions with increasing length towards the side arranged opposite to a gate pad structure.

FIG. 6 shows a cross-sectional view of a further embodiment having a single high resistance portion with a plurality of low resistance portions formed thereon.

FIG. 7 shows a plan view of another embodiment having a low and a high electrical resistance portion of substantially same length forming a ring-like gate runner structure.

FIG. 8 shows a plan view of another embodiment having a low and a high electrical resistance portion of different length forming a ring-like gate runner structure.

FIG. 9 shows an embodiment of a gate runner structure having high resistance portions integrated in the semiconductor substrate.

FIG. 10 shows a further embodiment of a gate runner structure in a plane view having a continuous high electrical resistance portion and two spaced-apart low electrical resistance portions formed thereon.

FIGS. 11A to 11D show steps for manufacturing a semiconductor device having a gate runner structure.

### DETAILED DESCRIPTION OF THE INVENTION

Reference will now be made in detail to various embodiments, one or more examples of which are illustrated in the figures. Each example is provided by way of explanation, and is not meant as a limitation of the invention. For example, features illustrated or described as part of one embodiment can be used on or in conjunction with other embodiments to yield yet a further embodiment. It is intended that the present invention includes such modifications and variations. The examples are described using specific language which should not be construed as limiting the scope of the appending claims. The drawings are not scaled and are for illustrative purposes only.

The term “lateral” as used in this specification intends to describe an orientation parallel to the main surface of a semiconductor wafer or die.

The term “vertical” as used in this specification intends to describe an orientation which is arranged perpendicular to the main surface of the semiconductor wafer or die.

The term “above” as used in this specification describes a location of a structural feature which is arranged closer to the first surface in relation to another structural feature.

Consequently, the term “below” as used in this specification describes a location of a structural feature which is arranged closer to the second surface in relation to another structural feature.

Specific embodiments described in this specification pertain to, without being limited thereto, semiconductor devices such as CMOS devices, power semiconductor devices and particularly to devices which are controlled by field-effect such as field-effect transistors (FETs) and insulated gate bipolar transistors (IGBTs).

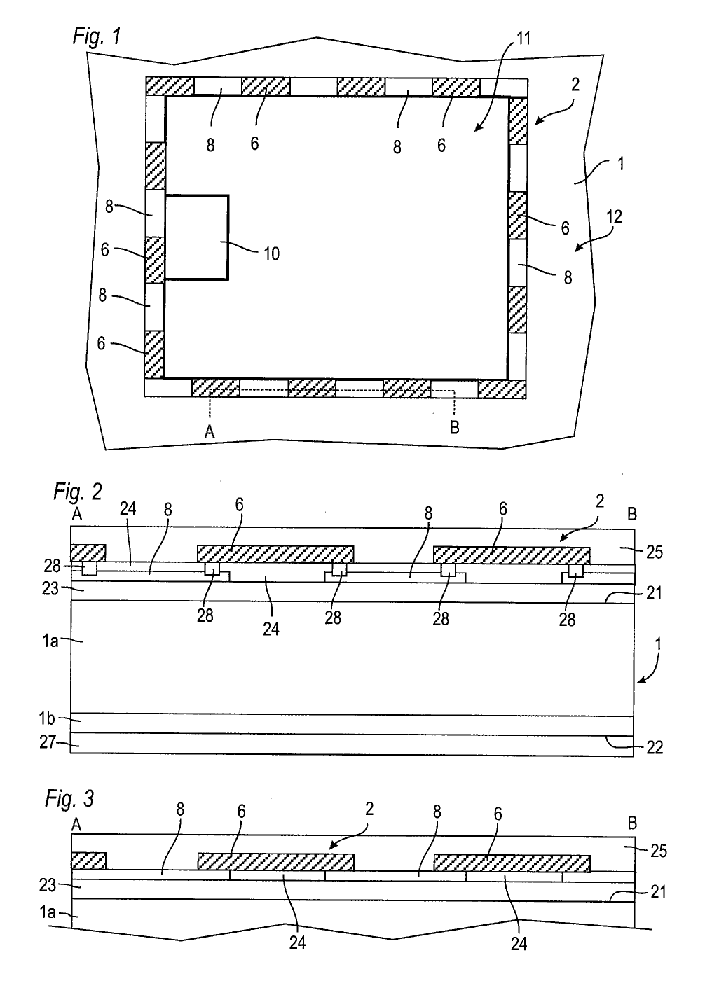

With reference to FIG. 1, a first embodiment of a semiconductor device is described. The semiconductor device includes a semiconductor substrate 1 and a gate runner structure 2 which includes at least one low electrical resistance portion 6 and at least one high electrical resistance portion 8 forming a resistor structure. Typically, the gate runner structure 2 has a plurality of low electrical resistance portions 6 and a plurality of high electrical resistance portions 8 such as at least two low electrical resistance portions 6 and at least one high electrical resistance portion 8, at least two low electrical resistance portions 6 and at least two high electrical resistance portions 8, at least three low electrical resistance portions 6 and at least two high electrical resistance portions 8, or even more low and high electrical resistance portions 6, 8. FIG. 1 shows an embodiment having fourteen low electrical resistance portions 6 and fourteen high electrical resistance portions 8. A skilled person will appreciate that the number of high and low electrical resistance portions 6, 8 can be selected according to specific needs.

In certain embodiments, the gate runner structure 2 includes at least two spaced-apart low electrical resistance portions 6 and at least one high electrical resistance portion 8 which electrically connects the two spaced-apart low electrical resistance portions 6 with each other. The resistance portions 6, 8 are therefore connected with each other in series.

The resistor structure integrated in the gate runner structure 2 can be scaled with the device and does not assume further space in comparison to resistors arranged separate to the gate runner structure 2. Furthermore, integrating a resistor structure into the gate runner structure 2 avoids additional parasitic effects such as parasitic capacitances and inductances of a bond pad and the corresponding bond wire or of additional electrical connections required. The resistor structure is formed by the at least one high electrical resistance portion, the length of which can be varied to obtain different resistance values.

The gate runner structure 2, hereinafter referred to as gate runner 2, can have a ring-like shape with a rectangular or hexagonal layout or any other layout depending on the actual layout of the semiconductor device. The gate runner 2 can be formed like a closed ring or a ring having an open side or can have a U-shaped layout. Furthermore, a stripe layout is also possible.

FIG. 1 shows the gate runner 2 in projection onto a first surface of the semiconductor substrate 1. In this specific embodiment, the gate runner 2 surrounds an active cell area 11 of the semiconductor device. An edge termination region 12 is arranged at least partially or completely around the active cell areas 11 with the gate runner 2 being arranged in the edge termination region 12 close to the active cell area 11. The active cell area 11 typically includes substantially identical active cells each having a gate electrode in electrical connection with the gate runner 2. For the sake of clarity, active cells 30, 30a each having a gate electrode 31, 31a are shown in FIG. 5. The skilled person will appreciate that the active cells 30, 30a can be of different type such as of planar or vertical type and can have a different layout such as a rectangular or hexagonal layout. The semiconductor device typically includes a plurality of substantially identical active cells which are connected with each other in parallel to allow switching of high currents.

FIG. 1 also shows a gate pad structure 10 arranged within the area surrounded by the gate runner 2. The gate pad structure 10 is in electrical contact with at least one of the low electrical resistance portions 6 of the gate runner 2. Two or more gate pad structures 10 can be provided if desired, for example when very large area devices are concerned. Alternatively, the gate pad structure 10 can be in electrical contact directly with one of the high electrical resistance portions 8. Typically, the gate pad structure 10 and the respective electrical resistance portions 6, 8 are electrically connected with each other in series.

In this description, the gate runner 2 and the gate electrodes of the active cells form together with the gate pad structure and the electrical connections between the gate electrodes and the runner 2 a gate structure, which may also include optional gate fingers. The gate structure has an effective gate resistance which is determined by all components and, particularly, by the gate runner 2. The effective gate resistance influences the switching behaviour of the active cells.

Gate runners are used particularly for large area semiconductor devices having a plurality of active cells to connect electrically the gate electrodes of all cells with a common gate pad structure. In some embodiments, it is desired that the electrical connection to each cell has the same resistance so that the cells can be uniformly activated. Otherwise, for example, when the effective gate resistance of cells close to the gate pad were smaller than for cells remote to the gate pad, the cells close to the gate pad would switch faster and would therefore bear the total current. This non-uniform behaviour is sometimes referred to as current splitting or formation of current filaments. Formation of current filaments stresses the active cells and can render the device inoperable.

The gate runner 2, as described herein, can be used to provide a uniform electrical connection to all gate electrodes so that each gate electrode “sees” substantially the same effective gate resistance. The cells are therefore uniformly switched and the risk of having a current splitting is reduced.

As shown in FIG. 1, low and high electrical resistance portions 6 and 8, respectively, alternate. Specific arrangements of the low and high electrical resistance portions 6, 8 can be used for optimising the switching behaviour. Furthermore, the devices can be custom-specific manufactured simply by varying the length or number of the respective electrical portions, or by adjusting the electrical resistance of the high electrical resistance portions. If desired, a substantially uniform electrical connection to the active cells of the device can be provided. Typically, low and high electrical resistance portions 6, 8 are connected in series with each other, typically in an alternating manner.

By combining high and low electrical resistance portions 6, 8 to form a gate runner 2 the electrical resistance of the gate runner 2 can be adjusted according to specific needs. Particularly, the resistance of the gate runner 2 can be selected to reduce oscillations of fast switching devices by increasing the effective gate resistance. Increasing the effective gate resistance reduces the switching speed of the device since the gates of the respective cells can only be charged or discharged at reduced speed. Increasing the effective gate resistance might increase switching losses which are, however, tolerable to a certain degree if, on the other hand, the risk, that the device is subjected to adverse oscillations, can be reduced. As it becomes more apparent from the description below, the effective gate resistance can be selected in a wide range which allows adjustment of the device behaviour to specific applications.

The effective gate resistance can be determined by an impedance measurement between source and drain of the semiconductor device. Alternatively, the effective gate resistance can be determined from a comparison between the switching behaviour of a reference device having a gate runner made of a low resistance material only and the switching behaviour of a device having a gate runner of low and high electrical resistance portions as described herein. An external resistor is connected to the gate runner of the reference device and varied until the switching behaviour of both devices is substantially identical. The effective gate resistance then corresponds to the value of the external resistor.

FIG. 2 shows a cross-sectional view vertical to the first surface 21 of the semiconductor substrate 1 along the line AB in FIG. 1. The semiconductor substrate 1 can be a single-crystalline wafer material or a combination of one or more epitaxial layers formed on a single-crystalline wafer. Multiple epitaxial layers, which are sequentially deposited, are used particularly for compensation devices having compensation structures integrated in the drift region. For power semiconductor applications, typically a low-doped epitaxial layer is deposited on a high-doped wafer for adjusting the breakthrough voltage. The semiconductor material can be silicon (Si), silicon carbide (SiC), a III-V semiconductor or a heterojunction-semiconductor made of, for example, a SiC-material with an additional Si epitaxial layer. In the specific embodiment shown in FIG. 2, 1b denotes a high-doped wafer while 1a denotes an epitaxial layer.

In the embodiment shown in FIG. 2, wafer 1b forms a drain region when the semiconductor device is a power FET. The drain region 1b is contacted by a back-side metallization 27. In case of an IGBT, wafer 1b would form an emitter region having an opposite conductivity type to epitaxial layer 1a which forms a drift region.

A first insulating layer 23, for example an oxide layer, is arranged on the first surface 21 of the semiconductor substrate 1. Thereon, high electrical resistance portions 8 are formed in a first level. The high electrical resistance portions 8 are covered by a second insulating layer 24, for example an oxide layer, on which the low electrical resistance portions 6 are arranged in a second level. First and second levels are spaced from each other in a vertical direction. With reference to the semiconductor substrate 1, the high electrical resistance portions 8 are arranged below the low electrical resistance portions 6 or between the substrate 1 and the low electrical resistance portions 6. It would also be possible to interchange the vertical arrangement of the low and high electrical resistance portions 6, 8.

The low electrical resistance portions 6 can be arranged in a staggered manner with respect to the high electrical resistance portions 8 as shown in FIGS. 2 and 3. Both, the low and high electrical resistance portions 6 and 8, respectively, can also be referred to as bridges for “bridging” the respective other spaced-apart resistance portions. The electrical connections between the low and high electrical resistance portions 6, 8 are provided by vias 28 formed in the second insulating layer 24. A third insulating layer 25 covers the low electrical resistance portions 6 and thus the gate runner 2.

As further shown in FIG. 2, the low electrical resistance portions 6 are formed spaced-apart and isolated from each other so that an electrical connection between two adjacent low electrical resistance portions 6 is only provided by a high electrical resistance portion 8. By appropriately selecting the number, size and length of the low and high electrical resistance portions 6, 8 any resistance of the gate runner 2 between the resistance of a gate runner formed completely with material of the low electrical resistance portions 6 and the resistance of a gate runner formed completely with material of the high electrical resistance portions 8 can be varied.

For example, the low electrical resistance portions 6 can be made of a metal-containing material such as a metal or a metal-alloy. In many applications, aluminium or an aluminium-alloy can be used which have a sufficiently low electrical resistance. On the other hand, the high electrical resistance portions 8 can be made of an appropriately doped polysilicon. The vias 28 typically are also made of a metal such as aluminium.

A skilled person will appreciate that the resistance of the low and high electrical resistance portions 6, 8 is determined by the specific electrical resistance and the cross-sectional area of the respective material used. Due to size limitations the width of the respective electrical resistance portions can not be significantly increased in many applications. Under certain circumstances, it might be possible to increase their thickness which, however, would increase topological differences between for example the edge termination region 12 and the active cell area 11. By selecting the doping concentration of polysilicon, a certain variation of the resistance is also possible.

To illustrate an application, a semiconductor device with a total area of about 30 mm² is assumed. In this case, the gate runner 2 having a ring-like structure as shown in FIG. 1 would lead to an effective gate resistance of about 1.5 Ohm when completely made of aluminium. If, on the other hand, the gate runner 2 would be formed completely of polysilicon having a sheet resistance of about 10 Ohm/square the effective gate resistance would be about 80 Ohm. An effective gate resistance of about 80 Ohm is too high for many applications and would increase switching losses. On the other hand, a low effective gate resistance of about 1.5 Ohm might not sufficiently suppress oscillations. Therefore, both materials are suitably combined to form a gate runner 2 having portions from both materials which, when connected in series, forming a gate runner 2 which results in an effective resistance between 1.5 Ohm and 80 Ohm. For example, a suitable effective gate resistance would be in the range from about 5 to 30 Ohm.

Depending on the device size, the effective gate resistance can be maintained by varying the relative contribution of the respective resistance portions to the gate runner 2. For example, to maintain the effective resistance at a designated value when manufacturing a large device, the total length of the low electrical resistance portions 6 can be increased with respect to the total length of the high electrical resistance portions 8 to take account of the increased size of the gate runner 2. On the other hand, for small devices the high electrical resistance portions 8 may dominate the gate runner 2 to keep the resistance at the designated value.

FIG. 3 shows another embodiment having a second insulating layer 24 etched back to flush with the upper surface of the high electrical resistance portions 8. In this case, the low electrical resistance portions 6 are in direct contact with the high electrical resistance portions 8. Vias are not required. Low and high electrical resistance portions 6, 8 are arranged to overlap partially each other as also shown in FIG. 2. The extent of the overlap determines the contact area between a high and a low electrical resistance portion 6, 8.

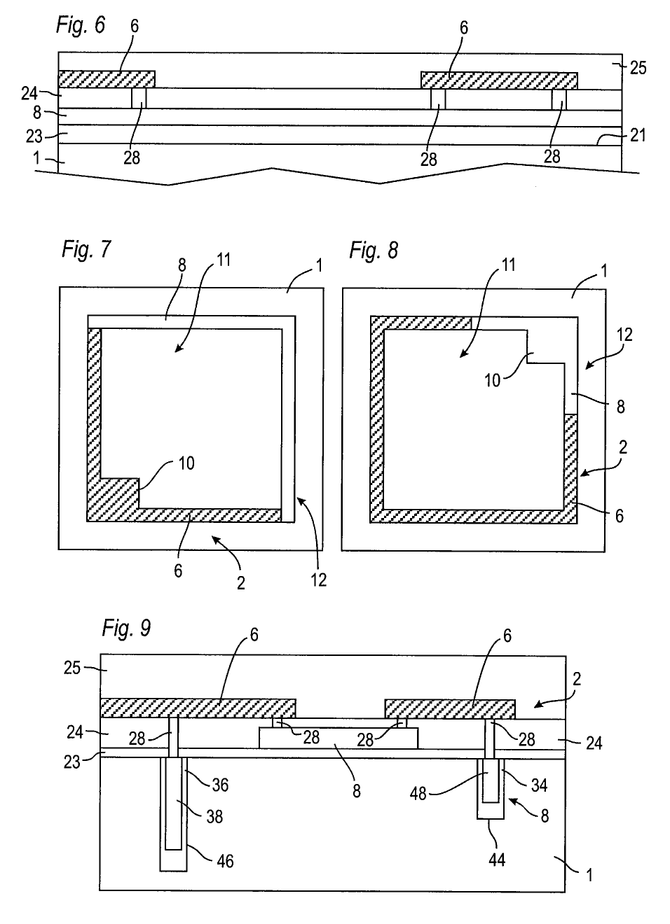

It would also be possible to form a single continuous high electrical resistance portion 8 and to add selectively low electrical resistance portions 6 to reduce the total resistance of the high electrical resistance portion 8. In this case, the high electrical resistance portion is not structured but formed as a single continuous opened or closed ring. Such an embodiment is illustrated in FIG. 6 showing a vertical cross-section along a gate runner.

In some embodiments, a further ring structure (not shown) can surround the gate runner 2 and functions as a source runner, i.e. provides an electrical connection for the source regions of the active cells.

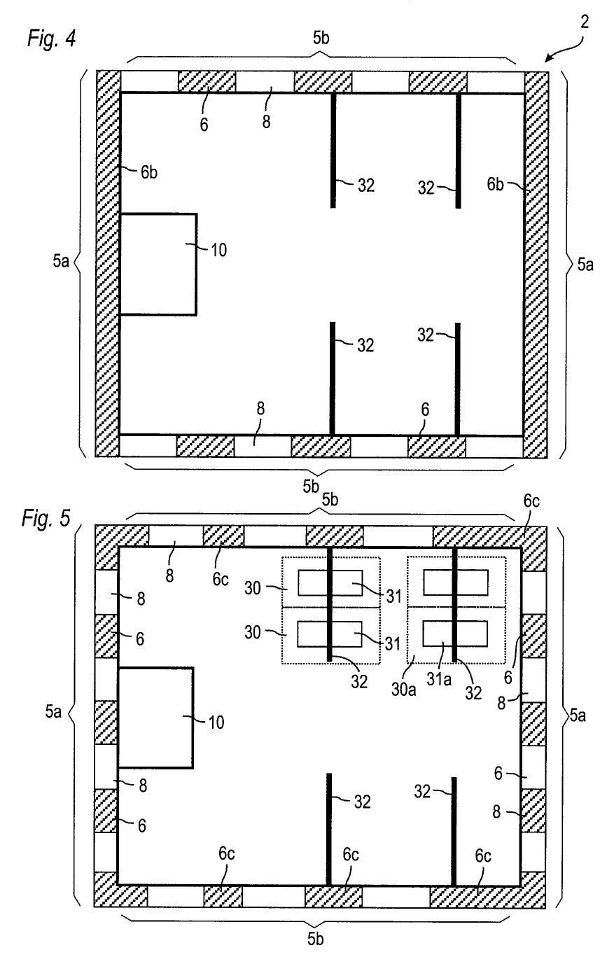

A further embodiment of a gate runner 2 is shown in FIG. 4. The gate runner 2 has two first sections 5a arranged opposite and running parallel to each other which are connected at their ends by two second sections 5b arranged opposite and running parallel to each other. The four sections 5a, 5b, each of which has an elongated shape, form together a rectangular-shaped gate runner 2. One of the first sections 5a is electrically connected to a gate pad structure 10 which can be arranged substantially in a central position with respect to the first section 5a. The gate pad structure 10 can also be arranged in a corner of a rectangular gate runner 2 or at any other location. Each of the first sections 5a is substantially formed by a single low electrical resistance portion 6b. Different thereto, each of the second sections 5b includes a combination of low and high electrical resistance portions 6 and 8 similar to the embodiment shown in FIG. 1. This arrangement reduces the lateral resistance of the gate runner 2, i.e. the resistance in a direction lateral to a notional line running parallel to the second sections 5b and through the centre of the gate pad structure 10. Furthermore, a more uniform switching of the active cells can be obtained since the cells are switched in rows (parallel to the first sections 5a) which reduces the risk of current splitting. Optional gate fingers 32 are shown in FIG. 4 which provides an electrical connection between the gate runner 2 and the gate electrodes of the active cells.

FIG. 5 shows another embodiment having two first sections 5a and two second sections 5b which are arranged in a similar manner as shown in FIG. 4. However, the layout of the section 5a, 5b differs from FIG. 4. First sections 5a, one of which is connected with gate pad structure 10, has an arrangement similar to the arrangement as shown in FIG. 1, i.e. has low electrical resistance portions 6 and high electrical resistance portions 8 of substantially equal length. Different thereto, each of the second sections 5b has low electrical resistance portions 6c of increasing length with increasing distance to the gate pad 10, i.e. low electrical resistance portions 6c with increased length are arranged remote to the gate pad structure 10.

When considering the electrical path between the gate pad structure 10 and each active cell, the electrical path to the most remote active cell 31a is longer than for an active cell such as cell 31 arranged closer to the gate pad structure 10. This means that the effective gate resistance of the most remote active cell 31a would be larger than that for cell 31. In order to at least partially compensate the different electrical path and hence the increased resistance thereof, low electrical resistance portions 6c with increasing length are arranged in the electrical path towards the most remote cell 31a to lessen the increase of the resistance. Alternatively or additionally, the length of the high electrical resistance portions 8 can be reduced.

A further embodiment is illustrated in FIG. 7. The gate structure 2 includes only one high electrical resistance portion 6 and one low electrical resistance portion 8, both of which are angular or L-shaped and form together a closed ring structure. In this embodiment, both the low and high electrical resistance portions 6, 8 have substantially the same length.

Different thereto, the embodiment shown in FIG. 8 has one high electrical resistance portion 8 which defines a significantly shorter electrical path than the low electrical resistance 6. Furthermore, the gate pad structure 10 is integrally formed with the high electrical resistance portion 8. The integral resistor structure of the embodiment shown in FIG. 8 is thus formed close to the gate pad structure 10 while the main portion of the gate runner 2 is formed by the low electrical resistance portion 6. This provides for a substantially uniform electrical connection of the cells in the active cell area. Alternatively, the gate pad structure 10 can be made of a metal or a metal-alloy to facilitate bonding and to reduce the connection resistance to the bond wire.

FIG. 9 illustrates another embodiment with the high electrical resistance portions 8 integrated in the semiconductor substrate 1. This can be done by using a conductive region 48 formed in a groove 44 of the semiconductor substrate 1.

The conductive region 48 can be doped polysilicon, which is insulated from the semiconductor substrate 1 by a groove insulating layer 34.

FIG. 9 also shows a gate electrode 38 arranged in a trench 46. Gate electrode 38 is insulated from the semiconductor substrate 1 by a gate dielectric layer 36. An electrical connection between a low electrical portion 6 formed above the semiconductor substrate 1 and the gate electrode 38 is provided by via 28.

Trench 46 and groove 44 can be concomitantly or separately formed. Furthermore, the groove insulating layer 34 and the gate dielectric layer 36 can also be formed together or in separate steps. Typically, the gate electrode 38 and the conductive region arranged in groove 44 are formed together. In this embodiment, groove 44 and trench 46 have different depths but can also be formed to have substantially the same depth.

In the embodiment shown in FIG. 9, the gate runner 2 has at least one high electrical resistance portion 8 arranged on the semiconductor substrate 1 and at least one high electrical resistance portion 8 arranged in a trench 44 integrated in the semiconductor substrate 1. A skilled person will appreciate that, alternative to the embodiment shown in FIG. 9, the or all high electrical resistance portions 8 can also be arranged in a trench or trenches 44 so that no additional high electrical resistance portion 8 arranged on the semiconductor substrate 1 is provided. This reduces topological differences between the edge termination region 12 and the active cell area 11.

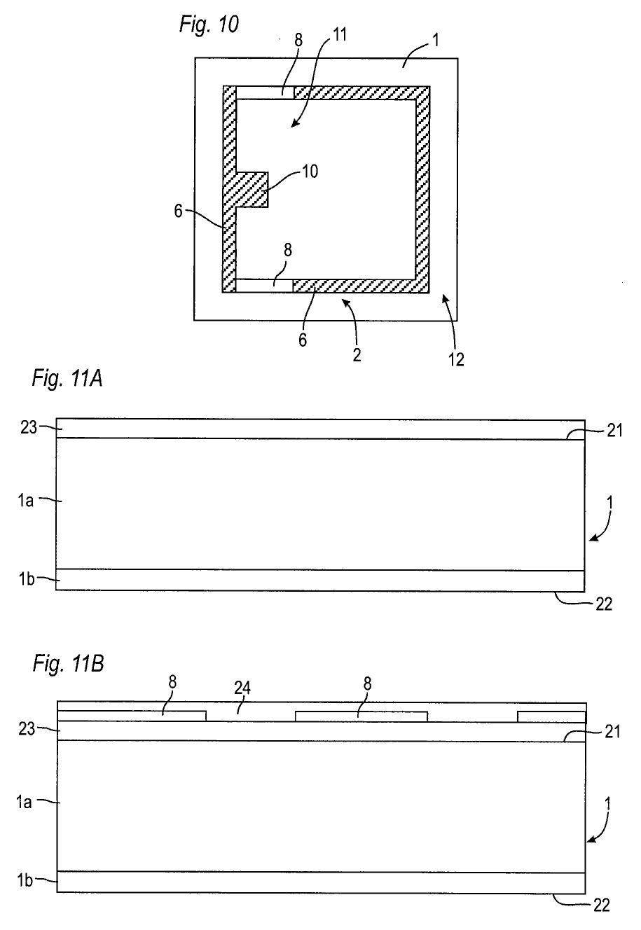

A plan view on a further embodiment is shown in FIG. 10. A single continuous high electrical resistance portion 8 completely surrounds the active cell area 11. Alternatively, the single high electrical resistance portion 8 can also partially surround the active cell area 11. Arranged above the single high electrical resistance portion 8, and partially covering it, there are arranged two spaced-apart low electrical resistance portions 6, on of which being integral with a gate pad structure 10. The low electrical resistance portions 6 are connected with the high electrical resistance portion 8 by vias (not shown) so that the low electrical resistance portions 6 are connected in series by the single high electrical resistance portion 8.

As shown in the embodiments, the arrangement of the gate runner 2 is typically, but not necessarily, symmetrical with respect to the gate pad structure 10, i.e. to a notional line running through the gate pad structure 10. A symmetrical arrangement improves a uniform switching of all cells.

From a manufacturing point, integrating the gate runner 2 with its internal resistor structure into the edge termination region 12 is possible by changing only three lithographical mask which are used for structuring polysilicon, metal layer and vias (contact openings). In some embodiments, only the lithographical masks for structuring the metal layer and for arranging the contact openings needs to be changed. Furthermore, it would be possible to change the specific electrical resistance or the sheet resistance of the high resistance electrical portions 8 by varying its doping concentration or thickness. These options facilitate custom-specific adaptation of the resistance of the gate runner 2.

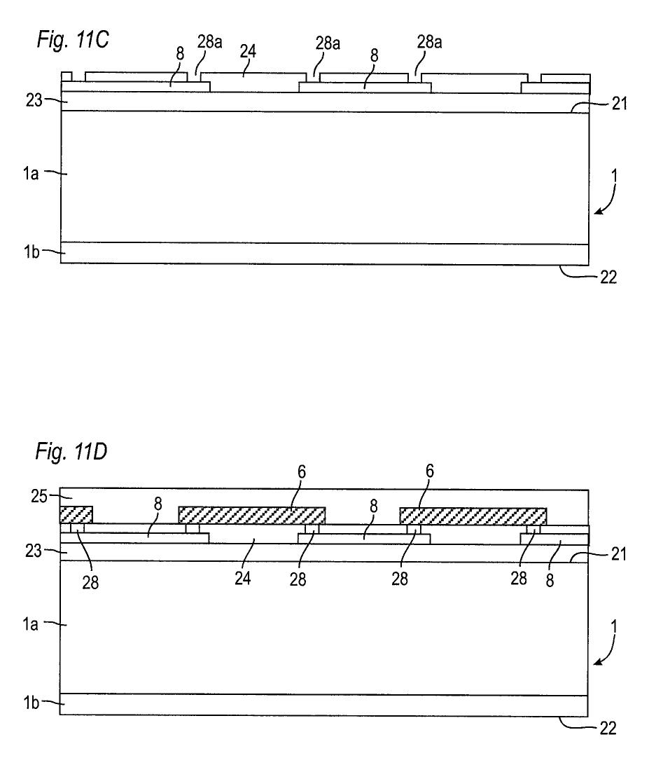

With reference to FIGS. 11A to 11D a method for manufacturing a semiconductor device having a gate runner is described.

Typically, a semiconductor substrate 1 having a first and second surface 21, 22 is provided. The semiconductor substrate 1 typically includes at least one epitaxial layer 1a formed on a single crystalline wafer 1b. The free surface of the epitaxial layer 1a forms the first surface 21 while the free surface of the wafer 1b forms the second surface 22 of the semiconductor substrate 1. Furthermore, active cells are formed in the epitaxial layer 1a, and each cell is substantially completed, i.e. includes source and body regions and gate electrodes. These elements are not shown in FIG. 11A.

After completing the active cells, a first insulating layer 23 is formed on the first surface 21 of the semiconductor substrate 1. Thereon, a gate runner is formed.

As shown in FIG. 11B, a polysilicon layer is deposited and structured to form high electrical resistance portions 8 in a first level. The polysilicon layer can be doped in-situ during deposition or subsequently to the deposition by an implantation step. Then, a second insulating layer 24 is deposited to cover the high electrical resistance portions. The resulting structure is shown in FIG. 11B.

In a further step, shown in FIG. 11C, openings 28a are formed in the second insulating layer 24 at selected locations to provide a contact to the buried high electrical resistance portions 8. Typically, the openings 28a are formed by anisotropic etching using a mask.

The openings 28a are then filled with a low resistance material such as aluminium to form vias 28 as shown in FIG. 11D. Next, low electrical resistance portions 6 are formed by depositing and structuring an aluminium layer. Alternatively, openings 28a can also be filled with the material of the aluminium layer for forming the low electrical resistance portions 6 to avoid a separate via filling step. A third insulating layer 25 is deposited to cover the low electrical resistance portions 6.

Together with the formation of the low electrical resistance portions 6 a gate pad structure 10 shown in FIGS. 1, 4, 5, 7 and 8 can be formed so that no additional processing steps are required.

The semiconductor device as described herein is not restricted to power applications but can be used for any application for which an adaptation of the effective gate resistance is desired.

The gate runner as described herein may include low and high electrical resistance portions which can be alternatingly connected in series to tailor the resistance of the gate runner and therefore the effective gate resistance of the device's gate structure. The resistance of the gate runner can be varied by changing at least one of the length, cross-section, and number of the respective resistance portions or by a suitable combination thereof. The gate runner can be used for devices with and without gate fingers.

The gate runner is integral to the semiconductor device, i.e. is not externally provided. This at least partially or completely prevents the addition of unwanted parasitic capacitances and inductances, i.e. additional bond pads and bond wires. Furthermore, the integrated gate runner does not require additional space since the low and high electrical resistance portions are arranged in two levels above each other. From the manufacturing point of view, the resistance of the gate runner can be varied by changing at least one of the layout, length, width, height, and a combination thereof.

The written description above uses specific embodiments to disclose the invention, including the best mode, and also to enable any person skilled in the art to make and use the invention. While the invention has been described in terms of various specific embodiments, those skilled in the art will recognize that the invention can be practiced with modifications within the spirit and scope of the claims. Especially, mutually non-exclusive features of the embodiments described above may be combined with each other. The patentable scope is defined by the claims, and may include other examples that occur to those skilled in the art. Such other examples are intended to be within the scope of the claims if they have structural elements that do not differ from the literal language of the claims, or if they include equivalent structural elements with insubstantial differences from the literal languages of the claims.

What is claimed is:

1. A semiconductor device, comprising:
a semiconductor substrate;
an active cell area comprising at least one active cell formed in the semiconductor substrate;
an edge termination region surrounding at least sections of the active cell area; and
an integrated gate runner structure arranged at least partially in the edge termination region, the integrated gate runner structure comprising at least one low electrical resistance portion and at least one high electrical resistance portion,
wherein the high electrical resistance portion is electrically connected in series to the low electrical resistance portion.

2. The semiconductor device of claim 1, wherein the integrated gate runner structure comprises a plurality of spaced-apart low electrical resistance portions and a plurality of high electrical resistance portions, wherein respective two adjacent low electrical resistance portions are electrically connected by a respective one of the high electrical resistance portions.

3. The semiconductor device of claim 2, wherein the high and low electrical resistance portions are alternatingly connected in series with each other.

4. The semiconductor device of claim 1, wherein the low electrical resistance portion is comprised of a metal-containing material.

5. The semiconductor device of claim 1, wherein the high electrical resistance portion is comprised of polysilicon.

6. The semiconductor device of claim 1, wherein the high electrical resistance portion is arranged in a trench integrated in the semiconductor substrate.

7. The semiconductor device of claim 1, wherein the semiconductor device comprises a plurality of active cells arranged in the active cell area, each of the active cells comprising a gate electrode, the gate electrodes being electrically connected to the gate runner structure.

8. The semiconductor device of claim 1, wherein the semiconductor device further comprises at least one gate pad structure in electrical contact with at least one of the low and high electrical resistance portions of the gate runner structure.

9. The semiconductor device of claim 1, wherein the gate runner structure is formed at least partially on or above a first surface of the semiconductor substrate.

10. The semiconductor device of claim 9, wherein the gate runner structure has a ring-like or U-shaped layout when viewed in projection onto the first surface.

11. The semiconductor device of claim 9, wherein the gate runner structure comprises two spaced-apart sections which run substantially parallel to each other when viewed in projection onto the first surface, wherein each of the two sections is substantially formed by a low electrical resistance portion, and wherein the two sections are electrically connected with each other by at least a further section of the gate runner structure, the further section comprising at least one high electrical resistance portion.

12. The semiconductor device of claim 9, wherein the gate runner structure comprises two spaced-apart sections which run substantially parallel to each other when viewed in projection onto the first surface, wherein each of the two sections comprises low electrical resistance portions of increasing length towards one of the end of the respective section, and wherein the two sections are electrically connected with each other by at least a further section of the gate runner structure.

13. The semiconductor device of claim 9, wherein the gate runner structure comprises two spaced-apart sections which run substantially parallel to each other when viewed in projection onto the first surface, wherein each of the two sections comprises high electrical resistance portions of reducing length towards one of the end of the respective section, and wherein the two sections are electrically connected with each other by at least a further section of the gate runner structure.

14. The semiconductor device of claim 1, wherein the high electrical resistance portion is arranged substantially in a first level and the low electrical resistance portions are arranged substantially in a second level.

15. The semiconductor device of claim 14, wherein the gate runner structure further comprises an insulating layer arranged between the low electrical resistance portions and the high electrical resistance portion, wherein vias are arranged in the insulating layer for electrically connecting the respective portions with each other.

16. A semiconductor device, comprising:
a semiconductor substrate;
an active cell area comprising at least one active cell integrated in the semiconductor substrate;
an edge termination region surrounding at least sections of the active cell area; and
an integrated gate runner structure at least partially integrated in the edge termination region, the integrated gate runner structure comprising an integrated resistance configured to increase the resistance of the gate runner structure.

17. The semiconductor device of claim 16, wherein the resistance comprises at least a low electrical resistance and a high electrical resistance which is electrically connected to the low electrical resistance.

18. A semiconductor device, comprising:
a semiconductor substrate;
an active cell area comprising at least one active cell integrated in the semiconductor substrate;
an edge termination region surrounding at least sections of the active cell area; and
an integrated gate runner structure arranged at least partially in the edge termination region, the integrated gate runner structure comprising at least two spaced-apart low electrical resistance portions and at least one high electrical resistance portion,
wherein the high electrical resistance portion electrically connects the two spaced-apart low electrical resistance portions with each other.

19. The semiconductor device of claim 18, wherein the high electrical resistance portion is arranged substantially in a first level and the low electrical resistance portions are arranged substantially in a second level being vertically spaced from the first level.

20. A method for manufacturing a semiconductor device comprising an integrated gate runner structure, comprising:
providing a semiconductor substrate comprising an active cell area which comprises at least one active cell and an edge termination region surrounding at least sections of the active cell area; and
integrating a gate runner structure in the edge termination region by forming at least a low electrical resistance portion and at least a high electrical resistance portion which is electrically connected to the low electrical resistance portion.

21. The method of claim 20, wherein the substrate comprises a first surface, and the forming the integrated gate runner structure step comprises:
forming the high electrical resistance portion in a first level above the first surface; and
forming the low electrical resistance portion in a second level above the first surface.

22. The method of claim 20, further comprising forming an insulating layer between the high electrical resistance portion and the low electrical resistance portion, and forming vias in the insulating layer for electrically connecting the respective portions with each other.

23. The method of claim 20, wherein the forming a spaced-apart low electrical resistance portion step comprises forming a plurality of low electrical resistance portions with different length.

24. The method of claim 20, further comprising forming at least one gate pad structure, wherein the gate runner structure is arranged substantially symmetrically with respect to the gate pad structure.

25. The method of claim 20, wherein the high electrical resistance portion is formed in a trench integrated in the semiconductor substrate.
